(19) United States
(12) Patent Application Publication
(10) Pub. No.: US 2018/0062022 A1
(43) Pub. Date: Mar. 1, 2018

(54) Sol-gel-based printable doping media which inhibit parasitic diffusion for the local doping of silicon wafers

(71) Applicant: Merck Patent GmbH, Darmstadt (DE)

(72) Inventors: Oliver DOLL, Dietzenbach (DE); Ingo KOEHLER, Darmstadt (DE); Sebastian BARTH, Darmstadt (DE)

(73) Assignee: Merck Patent GmbH, Darmstadt (DE)

(21) Appl. No.: 15/565,955

(22) PCT Filed: Mar. 24, 2016
(86) PCT No.: PCT/EP2016/000516

§ 371 Date: Oct. 12, 2017

(30) Foreign Application Priority Data
Apr. 15, 2015 (EP) 15001071.8
Aug. 12, 2015 (EP) 15180681.7

(51) Int. Cl. H01L 31/18; C23C 18/06; C23C 18/12

(52) U.S. Cl. CPC H01L 31/1804; C23C 18/06; H01L 21/2225; C23C 18/1254; C23C 18/1216

(57) ABSTRACT

The present invention relates to a novel printable paste in the form of a hybrid gel based on precursors of inorganic oxides which can be used in a simplified process for the production of solar cells, where the hybrid gel according to the invention functions both as doping medium and also as diffusion barrier.

The present invention relates to a novel printable paste in the form of a hybrid gel based on precursors of inorganic oxides which can be used in a simplified process for the production of solar cells, where the hybrid gel according to the invention functions both as doping medium and also as diffusion barrier.

### PRIOR ART

The production of simple solar cells or the solar cells which are currently represented with the greatest market share in the market comprises the essential production steps outlined below:

1) Saw-Damage Etching and Texture

A silicon wafer (monocrystalline, multicrystalline or quasi-monocrystalline, base doping p or n type) is freed from adherent saw damage by means of etching methods and “simultaneously” textured, generally in the same etching bath. Texturing is in this case taken to mean the creation of a preferentially aligned surface (nature) as a consequence of the etching step or simply the intentional, but not particularly aligned roughening of the wafer surface. As a consequence of the texturing, the surface of the wafer now acts as a diffuse reflector and thus reduces the directed reflection, which is dependent on the wavelength and on the angle of incidence, ultimately resulting in an increase in the absorbed proportion of the light incident on the surface and thus an increase in the conversion efficiency of the solar cell.

The above-mentioned etching solutions for the treatment of the silicon wafers typically consist, in the case of monocrystalline wafers, of dilute potassium hydroxide solution to which isopropyl alcohol has been added as solvent. Other alcohols having a higher vapour pressure or a higher boiling point than isopropyl alcohol may also be added instead if this enables the desired etching result to be achieved. The desired etching result obtained is typically a morphology which is characterised by pyramids having a square base which are randomly arranged, or rather etched out of the original surface. The density, the height and thus the base area of the pyramids can be partly influenced by a suitable choice of the above-mentioned components of the etching solution, the etching temperature and the residence time of the wafers in the etching tank. The texturing of the monocrystalline wafers is typically carried out in the temperature range from 70-<90° C., where up to 10 μm of material per wafer side can be removed by etching.

In the case of multicrystalline silicon wafers, the etching solution can consist of potassium hydroxide solution having a moderate concentration (10-15%). However, this etching technique is hardly still used in industrial practice. More frequently, an etching solution consisting of nitric acid, hydrofluoric acid and water is used. This etching solution can be modified by various additives, such as, for example, sulfuric acid, phosphoric acid, acetic acid, N-methylpyrrolidone, and also surfactants, enabling, inter alia, wetting properties of the etching solution and also its etching rate to be specifically influenced. These acidic etch mixtures produce a morphology of nested etching trenches on the surface. The etching is typically carried out at temperatures in the range between 4° C. and <10° C., and the amount of material removed by etching here is generally 4 μm to 6 μm.

Immediately after the texturing, the silicon wafers are cleaned intensively with water and treated with dilute hydrofluoric acid in order to remove the chemical oxide layer formed as a consequence of the preceding treatment steps and contaminants absorbed and adsorbed therein and also thereon, in preparation for the subsequent high-temperature treatment.

2) Diffusion and Doping

The wafers etched and cleaned in the preceding step (in this case p-type base doping) are treated with vapour consisting of phosphorus oxide at elevated temperatures, typically between 750° C. and <1000° C. During this operation, the wafers are exposed to a controlled atmosphere consisting of dried nitrogen, dried oxygen and phosphoryl chloride in a quartz tube in a tubular furnace. To this end, the wafers are introduced into the quartz tube at temperatures between 600 and 700° C. The gas mixture is transported through the quartz tube. During the transport of the gas mixture through the strongly warmed tube, the phosphoryl chloride decomposes to give a vapour consisting of phosphorus oxide (for example P₂O₅) and chlorine gas. The phosphorus oxide vapour precipitates, inter alia, on the wafer surfaces (coating). At the same time, the silicon surface is oxidised at these temperatures with formation of a thin oxide layer. The precipitated phosphorus oxide is embedded in this layer, causing mixed oxide of silicon dioxide and phosphorus oxide to form on the wafer surface. This mixed oxide is known as phosphosilicate glass (PSG). This PSG has different softening points and different diffusion constants with respect to the phosphorus oxide depending on the concentration of the phosphorus oxide present. The mixed oxide serves as diffusion source for the silicon wafer, where the phosphorus oxide diffuses in the course of the diffusion in the direction of the interface between PSG and silicon wafer, where it is reduced to phosphorus by reaction with the silicon at the wafer surface (silicothermally). The phosphorus formed in this way has a solubility in silicon which is orders of magnitude higher than in the glass matrix from which it has been formed and thus preferentially dissolves in the silicon owing to the very high segregation coefficient. After dissolution, the phosphorus diffuses in the silicon along the concentration gradient into the volume of the silicon. In this diffusion process, concentration gradients in the order of 10⁵ form between typical surface concentrations of 10²¹ atoms/cm² and the base doping in the region of 10¹⁶ atoms/cm². The typical diffusion depth is 250 to 500 nm and is dependent on the diffusion temperature selected (for example 880° C.), and the total exposure duration (heating & coating phase & drive-in phase & cooling) of the wafers in the strongly warmed atmosphere. During the coating phase, a PSG layer forms which typically has a layer thickness of 40 to 60 nm. The coating of the wafers with the PSG, during which diffusion into the volume of the silicon also already takes place, is followed by the drive-in phase. This can be decoupled from the coating phase, but is in practice generally coupled directly to the coating in terms of time and is therefore usually also carried out at the same temperature. The composition of the gas mixture here is adapted in such a way that the further supply of phosphoryl chloride is suppressed. During drive-in, the surface of the silicon is oxidised further by the oxygen present in the gas mixture, causing a phosphorus oxide-depleted silicon dioxide layer which likewise comprises phosphorus oxide to be generated between the actual doping source, the highly phosphorus oxide-enriched PSG, and the silicon wafer. The growth of this layer is very much faster in relation to the mass flow of the dopant from the source (PSG), since the oxide growth is accelerated by the high surface doping of the wafer itself (acceleration by one to two orders of magnitude). This enables depletion or separation of the doping source to be achieved in a certain manner, permeation of which with phosphorus oxide diffusing on is influenced by the material flow, which is dependent on the temperature and thus the diffusion coefficient. In this way, the doping of the silicon can be controlled in certain limits. A typical diffusion duration consisting of coating phase and drive-in phase is, for example, 25 minutes. After this treatment, the tubular furnace is automatically cooled, and the wafers can be removed from the process tube at temperatures between 600° C. and 700° C.

In the case of boron doping of the wafers in the form of n-type base doping, a different method is used, which will not be explained separately here. The doping in these cases is carried out, for example, with boron trichloride or boron tribromide. Depending on the choice of the composition of the gas atmosphere employed for the doping, the formation of a so-called boron skin on the wafers may be observed. This boron skin is dependent on various influencing factors: crucially the doping atmosphere, the temperature, the doping duration, the source concentration and the coupled (or linear-combined) parameters mentioned above.

In such diffusion processes, it goes without saying that the wafers used cannot contain any regions of preferred diffusion and doping (apart from those which are formed by inhomogeneous gas flows and resultant gas pockets of inhomogeneous composition) if the substrates have not previously been subjected to a corresponding pretreatment (for example structuring thereof with diffusion-inhibiting and/or -suppressing layers and materials).

For completeness, it should also be pointed out here that there are also further diffusion and doping technologies which have become established to different extents in the production of crystalline solar cells based on silicon. Thus, mention may be made of:
ion implantation,
doping promoted via the gas-phase deposition of mixed oxides, such as, for example, those of PSG and BSG (borosilicate glass), by means of APCVD, PECVD, MOCVD and LPCVD processes,
(co)sputtering of mixed oxides and/or ceramic materials and hard materials (for example boron nitride), gas-phase deposition of the latter two, purely thermal gas-phase deposition starting from solid dopant sources (for example boron oxide and boron nitride), and
liquid-phase deposition of liquids (inks) and pastes having a doping action.

The latter are frequently used in so-called inline doping, in which the corresponding pastes and inks are applied by means of suitable methods to the wafer side to be doped. After or also even during the application, the solvents present in the compositions employed for the doping are removed by temperature and/or vacuum treatment. This leaves the actual dopant behind on the wafer surface. Liquid doping sources which can be employed are, for example, dilute solutions of phosphoric or boric acid, and also sol-gel-based systems or also solutions of polymeric borazil compounds. Corresponding doping pastes are characterised virtually exclusively by the use of additional thickening polymers, and comprise dopants in suitable form. The evaporation of the solvents from the above-mentioned doping media is usually followed by treatment at high temperature, during which undesired and interfering additives, but ones which are necessary for the formulation, are either “burnt” and/or pyrolysed. The removal of solvents and the burning-out may, but do not have to, take place simultaneously. The coated substrates subsequently usually pass through a through-flow furnace at temperatures between 800° C. and 1000° C., where the temperatures may be slightly increased compared with gas-phase diffusion in the tubular furnace in order to shorten the passage time. The gas atmosphere prevailing in the through-flow furnace may differ in accordance with the requirements of the doping and may consist of dry nitrogen, dry air, a mixture of dry oxygen and dry nitrogen and/or, depending on the design of the furnace to be passed through, zones of one or other of the above-mentioned gas atmospheres. Further gas mixtures are conceivable, but currently do not have major importance industrially. A characteristic of inline diffusion is that the coating and drive-in of the dopant can in principle take place decoupled from one another.

3) Removal of the Dopant Source and Optional Edge Insulation

The wafers present after the doping are coated on both sides with more or less glass on both sides of the surface. “More or less” in this case refers to modifications which can be applied during the doping process: double-sided diffusion vs. quasi-single-sided diffusion promoted by back-to-back arrangement of two wafers in one location of the process boats used. The latter variant enables predominantly single-sided doping, but does not completely suppress diffusion on the back. In both cases, the current state of the art is removal of the glasses present after the doping from the surfaces by means of etching in dilute hydrofluoric acid. To this end, the wafers are on the one hand reloaded in batches into wet-process boats and with the aid of the latter dipped into a solution of dilute hydrofluoric acid, typically 2% to 5%, and left therein until either the surface has been completely freed from the glasses, or the process cycle duration, which represents a sum parameter of the requisite etching duration and the process automation by machine, has expired. The complete removal of the glasses can be established, for example, from the complete dewetting of the silicon wafer surface by the dilute aqueous hydrofluoric acid solution. The complete removal of a PSG is achieved within 210 seconds at room temperature under these process conditions, for example using 2% hydrofluoric acid solution. The etching of corresponding BSGs is slower and requires longer process times and possibly also higher concentrations of the hydrofluoric acid used. After the etching, the wafers are rinsed with water.

On the other hand, the etching of the glasses on the wafer surfaces can also be carried out in a horizontally operating process, in which the wafers are introduced in a constant flow into an etcher in which the wafers pass horizontally through the corresponding process tanks (inline machine). In this case, the wafers are conveyed on rollers either through the process tanks and the etching solutions present therein, or the etch media are transported onto the wafer surfaces by means of roller application. The typical residence time of the wafers during etching of the PSG is about 90 seconds, and the hydrofluoric acid used is somewhat more highly concentrated than in the case of the batch process in order to compensate for the shorter residence time as a consequence of an increased etching rate. The concentration of the hydrofluoric acid is typically 5%. The tank temperature may optionally additionally be slightly increased compared with room temperature (>25° C.<50° C.).

In the process outlined last, it has become established to carry out the so-called edge insulation sequentially at the same time, giving rise to a slightly modified process flow: edge insulation→glass etching. Edge insulation is a technical necessity in the process which arises from the system-inherent characteristic of double-sided diffusion, also in the case of intentional single-sided back-to-back diffusion. A large-area parasitic p-n junction is present on the (later) back of the solar cell, which is, for process-engineering reasons, removed partially, but not completely, during the later processing. As a consequence of this, the front and back of the solar cell will have been short-circuited via a parasitic and residue p-n junction (tunnel contact), which reduces the conversion efficiency of the later solar cell. For removal of this junction, the wafers are passed on one side over an etching solution consisting of nitric acid and hydrofluoric acid. The etching solution may comprise, for example, sulfuric acid or phosphoric acid as secondary constituents. Alternatively, the etching solution is transported (conveyed) via rollers onto the back of the wafer. About 1 μm of silicon (including the glass layer present on the surface to be treated) is typically removed by etching in this process at temperatures between 4° C. and 8° C. In this process, the glass layer still present on the opposite side of the wafer serves as a mask, which provides a certain protection against overetching onto this side. This glass layer is subsequently removed with the aid of the glass etching already described.

In addition, the edge insulation can also be carried out with the aid of plasma etching processes. This plasma etching is then generally carried out before the glass etching. To this end, a plurality of wafers are stacked one on top of the other, and the outside edges are exposed to the plasma. The plasma is fed with fluorinated gases, for example tetrafluoromethane. The reactive species occurring on plasma decomposition of these gases etch the edges of the wafer. In general, the plasma etching is then followed by the glass etching.

4) Coating of the Front Surface with an Antireflection Layer

After the etching of the glass and the optional edge insulation, the front surface of the later solar cells is coated with an antireflection coating, which usually consists of amorphous and hydrogen-rich silicon nitride. Alternative antireflection coatings are conceivable. Possible coatings may consist of titanium dioxide, magnesium fluoride, tin dioxide and/or corresponding stacked layers of silicon dioxide and silicon nitride. However, antireflection coatings having a different composition are also technically possible. The coating of the wafer surface with the above-mentioned silicon nitride essentially fulfils two functions: on the one hand the layer generates an electric field owing to the numerous incorporated positive charges, which can keep charge carriers in the silicon away from the surface and can considerably reduce the recombination rate of these charge carriers at the silicon surface (field-effect passivation), on the other hand this layer generates a reflection-reducing property, depending on its optical parameters, such as, for example, refractive index and layer thickness, which contributes to it being possible for more light to be coupled into the later solar cell. The two effects can increase the conversion efficiency of the solar cell. Typical properties of the layers currently used are: a layer thickness of ˜80 nm on use of exclusively the above-mentioned silicon nitride, which has a refractive index of about 2.05. The antireflection reduction is most clearly apparent in the light wavelength region of 600 nm. The directed and undirected reflection here exhibits a value of about 1% to 3% of the originally incident light (perpendicular incidence to the surface perpendicular of the silicon wafer).

The above-mentioned silicon nitride layers are currently generally deposited on the surface by means of the direct PECVD process. To this end, a plasma into which silane and ammonia are introduced is ignited in an argon gas atmosphere. The silane and the ammonia are reacted in the plasma via ionic and free-radical reactions to give silicon nitride and at the same time deposited on the wafer surface. The properties of the layers can be adjusted and controlled, for example, via the individual gas flows of the reactants. The deposition of the above-mentioned silicon nitride layers can also be carried out with hydrogen as carrier gas and/or the reactants alone. Typical deposition temperatures are in the range between 300° C. and 400° C. Alternative deposition methods can be, for example, LPCVD and/or sputtering.

5) Production of the Front Surface Electrode Grid

After deposition of the antireflection layer, the front surface electrode is defined on the wafer surface coated with silicon nitride. In industrial practice, it has become established to produce the electrode with the aid of the screen-printing method using metallic sinter pastes. However, this is only one of many different possibilities for the production of the desired metal contacts.

In screen-printing metallisation, a paste which is highly enriched with silver particles (silver content ≦80%) is generally used. The sum of the remaining constituents arises from the rheological assistants necessary for formulation of the paste, such as, for example, solvents, binders and thickeners. Furthermore, the silver paste comprises a special glass-frit mixture, usually oxides and mixed oxides based on silicon dioxide, borosilicate glass and also lead oxide and/or bismuth oxide. The glass frit essentially fulfils two functions: it serves on the one hand as adhesion promoter between the wafer surface and the mass of the silver particles to be sintered, on the other hand it is responsible for penetration of the silicon nitride top layer in order to facilitate direct ohmic contact with the underlying silicon. The penetration of the silicon nitride takes place via an etching process with subsequent diffusion of silver dissolved in the glass-frit matrix into the silicon surface, whereby the ohmic contact formation is achieved. In practice, the silver paste is deposited on the wafer surface by means of screen printing and subsequently dried at temperatures of about 200° C. to 300° C. for a few minutes. For completeness, it should be mentioned that double-printing processes are also used industrially, which enable a second electrode grid to be printed with accurate registration onto an electrode grid generated during the first printing step. The thickness of the silver metallisation is thus increased, which can have a positive influence on the conductivity in the electrode grid. During this drying, the solvents present in the paste are expelled from the paste. The printed wafer subsequently passes through a through-flow furnace. An furnace of this type generally has a plurality of heating zones which can be activated and temperature-controlled independently of one another. During passivation of the through-flow furnace, the wafers are heated to temperatures up to about 950° C. However, the individual wafer is generally only subjected to this peak temperature for a few seconds. During the remainder of the through-flow phase, the wafer has temperatures of 600° C. to 800° C. At these temperatures, organic accompanying substances present in the silver paste, such as, for example, binders, are burnt out, and the etching of the silicon nitride layer is initiated. During the short time interval of prevailing peak temperatures, the contact formation with the silicon takes place. The wafers are subsequently allowed to cool.

The contact formation process outlined briefly in this way is usually carried out simultaneously with the two remaining contact formations (cf. 6 and 7), which is why the term co-firing process is also used in this case.

The front surface electrode grid consists per se of thin fingers (typical number ≧68) which have a width of typically 80 μm to 140 μm, and also busbars having widths in the range from 1.2 mm to 2.2 mm (depending on their number, typically two to three). The typical height of the printed silver elements is generally between 10 μm and 25 μm. The aspect ratio is rarely greater than 0.3.

6) Production of the Back Surface Busbars

The back surface busbars are generally likewise applied and defined by means of screen-printing processes. To this end, a similar silver paste to that used for the front surface metallisation is used. This paste has a similar composition, but comprises an alloy of silver and aluminium in which the proportion of aluminium typically makes up 2%. In addition, this paste comprises a lower glass-frit content. The busbars, generally two units, are printed onto the back of the wafer by means of screen printing with a typical width of 4 mm and are compacted and sintered as already described under point 5.

7) Production of the Back Surface Electrode

The back surface electrode is defined after the printing of the busbars. The electrode material consists of aluminium, which is why an aluminium-containing paste is printed onto the remaining free area of the wafer back by means of screen printing with an edge separation <1 mm for definition of the electrode. The paste is composed of ≦80% of aluminium. The remaining components are those which have already been mentioned under point 5 (such as, for example, solvents, binders, etc.). The aluminium paste is bonded to the wafer during the co-firing by the aluminium particles beginning to melt during the warming and silicon from the wafer dissolving in the molten aluminium. The melt mixture functions as dopant source and releases aluminium to the silicon (solubility limit: 0.016 atom percent), where the silicon is p⁺-doped as a consequence of this drive-in. During cooling of the wafer, a eutectic mixture of aluminium and silicon, which solidifies at 577° C. and has a composition having a mole fraction of 0.12 of Si, deposits, inter alia, on the wafer surface.

As a consequence of the drive-in of the aluminium into the silicon, a highly doped p-type layer, which functions as a type of mirror (“electric mirror”) on parts of the free charge carriers in the silicon, forms on the back of the wafer. These charge carriers cannot overcome this potential wall and are thus kept away from the back wafer surface very efficiently, which is thus evident from an overall reduced recombination rate of charge carriers at this surface. This potential wall is generally referred to as “back surface field”.

The sequence of the process steps described under points 5, 6 and 7 may, but does not have to, correspond to the sequence outlined here. It is evident to the person skilled in the art that the sequence of the outlined process steps can in principle be carried out in any conceivable combination.

8) Optional Edge Insulation

If the edge insulation of the wafer has not already been carried out as described under point 3, this is typically carried out with the aid of laser-beam methods after the co-firing. To this end, a laser beam is directed at the front of the solar cell, and the front surface p-n junction is parted with the aid of the energy coupled in by this beam. Cut trenches having a depth of up to 15 μm are generated here as a consequence of the action of the laser. Silicon is removed from the treated site via an ablation mechanism or ejected from the laser trench. This laser trench typically has a width of 30 μm to 60 μm and is about 200 μm away from the edge of the solar cell.

After production, the solar cells are characterised and classified in individual performance categories in accordance with their individual performances.

The person skilled in the art is familiar with solar-cell architectures with both n-type and also p-type base material. These solar cell types include, inter alia,
PERC solar cells,
PERL solar cells,
PERT solar cells,
MWT-PERT and MWT-PERL solar cells derived therefrom,
bifacial solar cells,
back surface contact cells,
back surface contact cells with interdigital contacts (IBC cells).

The choice of alternative doping technologies, as an alternative to the gas-phase doping already described in the introduction, is generally also incapable of solving the problem of the creation of locally differently doped regions on the silicon substrate. Alternative technologies which may be mentioned here are the deposition of doped glasses, or of amorphous mixed oxides, by means of PECVD and APCVD processes. Thermally induced doping of the silicon located beneath these glasses can easily be achieved from these glasses. In order to create locally differently doped regions, however, these glasses must be etched by means of mask processes in order to produce the corresponding structures from them. Alternatively, structured diffusion barriers against the deposition of the glasses can be deposited on the silicon wafers in order thus to define the regions to be doped. However, it is disadvantageous in this process that in each case only one polarity (n or p) of the doping can be achieved. Somewhat simpler than the structuring of the doping sources or of any diffusion barriers is direct laser beam-supported drive-in of dopants from dopant sources deposited in advance on the wafer surfaces. This process enables expensive structuring steps to be saved. Nevertheless, the disadvantage of possibly desired simultaneous doping of two polarities on the same surface at the same time (co-diffusion) cannot be compensated for, since this process is likewise based on pre-deposition of a dopant source which is only activated subsequently for the release of the dopant. A disadvantage of this (post)doping from such sources is the unavoidable laser damage of the substrate: the laser beam must be converted into heat by absorption of the radiation. Since the conventional dopant sources consist of mixed oxides of silicon and the dopants to be driven in, i.e. of boron oxide in the case of boron, the optical properties of these mixed oxides are consequently fairly similar to those of silicon oxide. These glasses (mixed oxides) therefore have a very low absorption coefficient for radiation in the relevant wavelength range. For this reason, the silicon located under the optically transparent glasses is used as absorption source. The silicon is in some cases warmed here until it melts, and consequently warms the glass located above it. This facilitates diffusion of the dopants—and does so a multiple faster than would be expected at normal diffusion temperatures, so that a very short diffusion time for the silicon arises (less than 1 second). The silicon is intended to cool again relatively quickly after absorption of the laser radiation as a consequence of the strong dissipation of the heat into the remaining, non-irradiated volume of the silicon and solidify epitactically on the non-molten material. However, the overall process is in reality accompanied by the formation of laser radiation-induced defects, which may be attributable to incomplete epitactic solidification and the formation of crystal defects. This can be attributed, for example, to dislocations and formation of vacancies and flaws as a consequence of the shock-like progress of the process. A further disadvantage of laser beam-supported diffusion is the relative inefficiency if relatively large areas are to be doped quickly, since the laser system scans the surface in a dot-grid process. This disadvantage is unimportant in the case of narrow regions to be doped. However, laser doping requires sequential deposition of the post-treatable glasses.

### OBJECT OF THE PRESENT INVENTION

The doping technologies usually used in the industrial production of solar cells, especially by gas phase-promoted diffusion with reactive precursors, such as phosphoryl chloride and/or boron tribromide, do not enable local dopings and/or locally different dopings to be generated on silicon wafers in a targeted manner. The creation of such structures using known doping technologies is only possible through complex and expensive structuring of the substrates. During the structuring, various masking processes must be matched to one another, which makes industrial mass production of such substrates very complex. For this reason, concepts for the production of solar cells which require such structuring have hitherto not been able to establish themselves. The object of the present invention is therefore to provide an inexpensive process which is simple to carry out, and a medium which can be employed in this process, whereby these problems and the masking steps which are normally necessary are obsolete and are thus eliminated. In addition, the doping source which can be applied locally is distinguished by the fact that it can preferably be applied to wafer surfaces by means of the screen printing process. For this purpose, the doping source must have a sufficiently pasty behaviour which, in contrast to the classical procedure, can and must be adjusted specifically without the use of viscosity-influencing polymeric additives, which may themselves represent an uncontrolled source of contamination. It has been found that a sufficiently pasty nature can be established by controlled gelling of the hybrid gels according to the invention. The pseudoplasticity of the hybrid gels can furthermore be adjusted further as desired in a very advantageous manner by the addition of waxes and wax-like additives. As a consequence of formulations adapted in this way, pastes whose pseudoplasticity can be adjusted very well and which have adequate shear resistance can be obtained. The waxes and wax-like additives used for the formulation are dissolved and/or melted in the gelled paste mixture. As a consequence of a suitable choice of the above-mentioned compounds and optionally mixtures thereof, and optionally with addition of assistants named more precisely in a further context, screen printing pastes which can be screen-printed very well and are homogeneous (one-phase) to formulated as temporarily emulsifying (two-phase) are obtained. The waxes and wax-like additives used in the formulation have an associative and co-thickening action in synthesised and gelled pastes, without the additives being thickeners in the classical sense. Furthermore, the waxes and wax-like compounds which influence the pseudoplasticity in an associative manner advantageously affect the establishment of the glass layer thickness resulting from the printed hybrid gels and also the individual drying-induced stress resistance thereof.

### BRIEF DESCRIPTION OF THE INVENTION

The present invention therefore relates to printable, paste-form hybrid gels based on precursors, such as of silicon dioxide, aluminium oxide and boron oxide, which are preferably printed onto silicon surfaces by means of the screen printing process for the purposes of local and/or full-area diffusion and doping on one side in the production of solar cells, preferably of highly efficient solar cells doped in a structured manner, dried during subsequent storage and subsequently brought to specific doping of the substrate itself by means of a suitable high-temperature process for release of the boron oxide precursor present in the hybrid gel to the substrate located beneath the boron paste. These are paste-form, printable hybrid gels having a viscosity >500 mPa*s based on precursors of the following oxide materials:

a) silicon dioxide: symmetrically and asymmetrically mono- to tetrasubstituted carboxy-, alkoxy- and alkoxyalkylsilanes, explicitly containing alkylalkoxysilanes, in which the central silicon atom can have a degree of substitution of 1 to 4 by at least one hydrogen atom bonded directly to the silicon atom, such as, for example, triethoxysilane, and where furthermore a degree of substitution relates to the number of possible carboxyl and/or alkoxy groups present, which, both in the case of alkyl and/or alkoxy and/or carboxyl groups, contain individual or different saturated, unsaturated branched, unbranched aliphatic, alicyclic and aromatic radicals, which may in turn be functionalised at any desired position of the alkyl, alkoxide or carboxyl radical by heteroatoms selected from the group O, N, S, Cl and Br, and mixtures of the above-mentioned precursors; individual compounds which satisfy the above-mentioned demands are: tetraethyl orthosilicate and the like, triethoxysilane, ethoxytrimethylsilane, dimethyldimethoxysilane, dimethyldiethoxysilane, triethoxyvinylsilane, bis[triethoxysilyl]ethane and bis[diethoxymethylsilyl]ethane

b) aluminium oxide: symmetrically and asymmetrically substituted aluminium alcoholates (alkoxides), such as aluminium triethanolate, aluminium triisopropylate, aluminium tri-sec-butylate, aluminium tributylate, aluminium triamylate and aluminium triisopentanolate, aluminium tris(β-diketones), such as aluminium acetylacetonate or aluminium tris(1,3-cyclohexanedionate), aluminium tris(β-ketoesters), aluminium monoacetylacetonate monoalcoholate, aluminium tris(hydroxyquinolate), aluminium soaps, such as mono- and dibasic aluminium stearate and aluminium tristearate, aluminium carboxylates, such as basic aluminium acetate, aluminium triacetate, basic aluminium formate, aluminium triformate and aluminium trioctanoate, aluminium hydroxide, aluminium metahydroxide and aluminium trichloride and the like, and mixtures thereof

c) boron oxide: diboron oxide, simple alkyl borates, such as triethyl borate, triisopropyl borate, boric acid esters of functionalised 1,2-glycols, such as, for example, ethylene glycol, functionalised 1,2,3-triols, such as, for example, glycerol, functionalised 1,3-glycols, such as, for example, 1,3-propanediol, boric acid esters with boric acid esters which contain the above-mentioned structural motifs as structural sub-units, such as, for example, 2,3-dihydroxysuccinic acid and enantiomers thereof, boric acid esters of ethanolamine, diethanolamine, triethanolamine, propanolamine, dipropanolamine and tripropanolamine, mixed anhydrides of boric acid and carboxylic acids, such as, for example, tetraacetoxy diborate, boric acid, metaboric acid, and mixtures of the above-mentioned precursors, which are brought to partial or complete intra- and/or interspecies condensation under water-containing or anhydrous conditions with the aid of the sol-gel technique, either simultaneously or sequentially, where the degree of gelling of the hybrid gel formed can be controlled specifically and influenced in the desired manner as a consequence of the condensation conditions set, such as precursor concentrations, water content, catalyst content, reaction temperature and time, the addition of condensation-controlling agents, such as, for example, various above-mentioned complexing agents and chelating agents, various solvents and individual volume fractions thereof, and also the specific elimination of readily volatile reaction assistants and disadvantageous by-products, giving storage-stable, very readily screen-printable and printing-stable and thus sufficiently shear-stable formulations.

The printable, paste-form hybrid gels obtained in this way, as described in greater detail below, can be influenced with respect to their degree of condensation through the choice of suitable reaction conditions so that high-viscosity mixtures in the form of pasty formulations or also pastes which can be processed and applied to substrates in the manner already claimed using printing processes which are suitable for such mixtures are present.

The printable paste-form hybrid gel according to the invention is a composition which can be adjusted with respect to its pasty and pseudoplastic properties by the addition of waxes and wax-like compounds in an amount of up to 25%, based on the entire finished mixture of the paste, where the waxes and wax-like compounds are selected from the group beeswax, Synchro wax, lanolin, carnauba wax, jojoba, Japan wax and the like, fatty acids and fatty alcohols, fatty glycols, esters of fatty acids and fatty alcohols, fatty aldehydes, fatty ketones and fatty β-diketones and mixtures thereof, where the above-mentioned classes of substance should each contain branched and unbranched carbon chains having chain lengths greater than or equal to twelve carbon atoms, have a thickening action in one phase and/or two phases, emulsifying or suspending, and thus render the classical use of polymeric thickeners superfluous.

The printable hybrid gel according to the invention thus provided is particularly suitable for use as doping medium in the processing of silicon wafers for photovoltaic, microelectronic, micromechanical and micro-optical applications.

In particular, the novel paste-form hybrid gels described here are suitable for the production of PERC, PERL, PERT and IBC solar cells and further particularly high-performance solar cells which have further architectural features, such as MWT, EWT, selective emitter, selective front surface field, selective back surface field and bifaciality.

It has proven particularly advantageous that the printable hybrid gels according to the invention can be employed for the production of touch-dry and abrasion-resistant layers on silicon wafers. For the production of these layers, after application in a temperature range between 50° C. and 750° C., preferably between 50° C. and 500° C., particularly preferably between 50° C. and 400° C., the hybrid gel is dried using one or more heating steps to be carried out sequentially (heating by means of a step function) and/or a heating ramp and compacted for vitrification, resulting in the formation of touch-dry and abrasion-resistant layers having a thickness of up to 500 nm.

Furthermore, it has been found by means of experiments that the use of the printable hybrid gel according to the invention enables the conductivity of the substrate to be influenced through corresponding layers applied to surfaces being dried, compacted and vitrified and silicon-doping atoms, such boron as in this case, being released to the substrate from the vitrified layers by heat treatment at a temperature in the range between 750° C. and 1100° C., preferably between 850° C. and 1100° C., particularly preferably between 850° C. and 1000° C.

It has proven particularly advantageous in the use of the printable pasty hybrid gels according to the invention that they facilitate different doping of various regions in a single process step, more precisely through suitable temperature treatment, doping of the printed substrate and simultaneously and/or sequentially doping of the unprinted silicon wafer surfaces with dopants of the opposite polarity by means of conventional gas-phase diffusion, and where the printed-on hybrid gel acts as diffusion barrier against the dopants of the opposite polarity. Processes for the production of solar cells using the paste-form hybrid gel according to the invention are characterised in that

a) hybrid gels are printed onto silicon wafers, the printed-on gels are dried and compacted and subsequently subjected to subsequent gas-phase diffusion with, for example, phosphoryl chloride, giving p-type dopings in the printed regions of the wafers and n-type dopings in the regions subjected exclusively to gas-phase diffusion,

or

b) hybrid gel deposited onto the silicon wafer over a large area is compacted, and local doping of the underlying substrate material is initiated from the dried and/or compacted paste with the aid of laser irradiation, followed by high-temperature diffusion and doping for the production of two-stage p-type doping levels in the silicon,

or

c) the silicon wafer is printed locally with the hybrid gel, where the structured deposition may optionally have alternating lines, the printed structures are dried and compacted and subsequently coated over the entire surface and encapsulated with the aid of PVD- and/or CVD-deposited doped glasses which are able to induce doping of the opposite polarity in silicon, and the entire overlapping structure is brought to structured doping of the silicon wafer by suitable high-temperature treatment, where the printed-on hybrid gel acts as diffusion barrier against the glass located on top and the dopant present therein.

### DETAILED DESCRIPTION

It has been found that the problems described above can be solved by a process for the preparation of printable, high-viscosity oxide media (viscosity >500 mPas) if pasty high-viscosity media (pastes) are prepared in a sol-gel-based synthesis by condensation of suitable precursors of silicon dioxide and aluminium oxide, mixed with precursors of boron oxide, and by controlled gelling.

In this connection, a paste is taken to mean a composition which, as a consequence of the sol-gel-based synthesis, has a high viscosity of greater than 500 mPa*s and is no longer flowable.

In accordance with the invention, the printable, high-viscosity oxide media, also called simply hybrid gels below, can be prepared in random proportions from suitable precursors at least of the following oxides: aluminium oxide, silicon dioxide and boron oxide—where the correspondingly named precursors are taken to mean at least the following compounds and classes of compound:

Silicon dioxide: symmetrically and asymmetrically mono- to tetrasubstituted carboxy-, alkoxy- and alkoxyalkylsilanes, explicitly containing alkylalkoxysilanes, in which the central silicon atom can have a degree of substitution of 1 to 4 by at least one hydrogen atom bonded directly to the silicon atom, such as, for example, triethoxysilane, and where furthermore a degree of substitution relates to the number of possible carboxyl and/or alkoxy groups present, which, both in the case of alkyl and/or alkoxy and/or carboxyl groups, contain individual or different saturated, unsaturated branched, unbranched aliphatic, alicyclic and aromatic radicals, which may in turn be functionalised at any desired position of the alkyl, alkoxide or carboxyl radical by heteroatoms selected from the group O, N, S, Cl and Br, and mixtures of the above-mentioned precursors; individual compounds which satisfy the above-mentioned demands are: tetraethyl orthosilicate and the like, triethoxysilane, ethoxytrimethylsilane, dimethyldimethoxysilane, dimethyldiethoxysilane, triethoxyvinylsilane, bis[triethoxysilyl]ethane and bis[diethoxymethylsilyl]ethane.

Aluminium oxide: symmetrically and asymmetrically substituted aluminium alcoholates (alkoxides), such as aluminium triethanolate, aluminium triisopropylate, aluminium tri-sec-butylate, aluminium tributylate, aluminium triamylate and aluminium triisopentanolate, aluminium tris(β-diketones), such as aluminium acetylacetonate or aluminium tris(1,3-cyclohexanedionate), aluminium tris(β-ketoesters), aluminium monoacetylacetonate monoalcoholate, aluminium tris(hydroxyquinolate), aluminium soaps, such as mono- and dibasic aluminium stearate and aluminium tristearate, aluminium carboxylates, such as basic aluminium acetate, aluminium triacetate, basic aluminium formate, aluminium triformate and aluminium trioctanoate, aluminium hydroxide, aluminium metahydroxide and aluminium trichloride and the like, and mixtures thereof.

Boron oxide: diboron oxide, simple alkyl borates, such as triethyl borate, triisopropyl borate, boric acid esters of functionalised 1,2-glycols, such as, for example, ethylene glycol, functionalised 1,2,3-triols, such as, for example, glycerol, functionalised 1,3-glycols, such as, for example, 1,3-propanediol, boric acid esters with boric acid esters which contain the above-mentioned structural motifs as structural sub-units, such as, for example, 2,3-dihydroxysuccinic acid and enantiomers thereof, boric acid esters of ethanolamine, diethanolamine, triethanolamine, propanolamine, dipropanolamine and tripropanolamine, mixed anhydrides of boric acid and carboxylic acids, such as, for example, tetraacetoxy diborate, boric acid, metaboric acid, and mixtures of the above-mentioned precursors.

The possible combinations are furthermore not necessarily restricted to the above-mentioned possible compositions: further substances which are able to impart advantageous properties on the gels may be present as additional components in the hybrid gels. They may be: oxides, basic oxides, hydroxides, alkoxides, carboxylates, β-diketonates, β-ketoesters, silicates and the like of cerium, tin, zinc, titanium, zirconium, hafnium, zinc, germanium, gallium, niobium, yttrium, which can be used directly or in pre-condensed form in the sol-gel synthesis. The hybrid gels can be prepared with the aid of an anhydrous or water-containing sol-gel synthesis. Further assistants which can advantageously be used in the formulation of the gels are the following substances:
surfactants, tensioactive compounds for influencing the wetting and drying behaviour,
antifoams and deaerators for influencing the drying behaviour,
strong carboxylic acids for initiation of the condensation reaction of oxide precursors, at least the following may serve as suitable carboxylic acids: formic acid, acetic acid, oxalic acid, trifluoroacetic acid, mono-, di- and tri-chloroacetic acid, glyoxalic acid, tartaric acid, maleic acid, malonic acid, pyruvic acid, malic acid, 2-oxoglutaric acid,
high- and low-boiling polar protic and aprotic solvents for influencing the particle size distribution, the degree of pre-condensation, the condensation, wetting and drying behaviour and the printing behaviour,
particulate additives for influencing the rheological properties,
particulate additives (for example aluminium hydroxides and aluminium oxides, colloidally precipitated or highly disperse silicon dioxide, tin dioxide, boron nitride, silicon carbide, silicon nitride, aluminium titanate, titanium dioxide, titanium carbide, titanium nitride, titanium carbonitride) for influencing the dry-film thicknesses resulting after drying and the morphology thereof,
particulate additives (for example aluminium hydroxides and aluminium oxides, colloidally precipitated or highly disperse silicon dioxide, tin dioxide, boron nitride, silicon carbide, silicon nitride, aluminium titanate, titanium dioxide, titanium carbide, titanium nitride, titanium carbonitride) for influencing the scratch resistance of the dried films,
capping agents selected from the group acetoxytrialkylsilanes, alkoxytrialkylsilanes, halotrialkylsilanes and derivatives thereof for influencing the condensation rates and the storage stability,
waxes and wax-like compounds, such as beeswax, Syncrowax, lanolin, carnauba wax, jojoba, Japan wax and the like, fatty acids and fatty alcohols, fatty glycols, esters of fatty acids and fatty alcohols, fatty aldehydes, fatty ketones and fatty β-diketones and mixtures thereof, where the above-mentioned classes of substance should each contain branched and unbranched carbon chains having chain lengths greater than or equal to twelve carbon atoms.

The hybrid gels can on the one hand be sterically stabilised and on the other hand specifically influenced and controlled with respect to their condensation and gelling rate, but also with respect to the rheological properties, by addition of suitable masking agents, complexing agents and chelating agents in a sub- to fully stoichiometric ratio. Suitable masking agents and complexing agents, as well as chelating agents, are, for example, acetylacetone, 1,3-cyclohexanedione, isomeric compounds of dihydroxybenzoic acids, acetaldoxime, and also, in addition, those which are disclosed and present in the patent applications WO 2012/119686 A, WO 2012119685 A1, WO 2012119684 A, EP 12703458.5 and EP 12704232.3. The contents of these specifications are therefore incorporated into the disclosure content of the present application.

The hybrid gels can be applied to the surface of silicon wafers with the aid of printing and coating processes. Suitable processes for this purpose may be: spin or dip coating, drop casting, curtain or slot-dye coating, screen or flexographic printing, gravure, ink-jet or aerosol-jet printing, offset printing, micro-contact printing, electrohydrodynamic dispensing, roller or spray coating, ultrasonic spray coating, pipe jetting, laser transfer printing, pad printing or rotary screen printing. The printing of the hybrid gels is preferably carried out using the screen printing process. The hybrid gels printed onto the surfaces of silicon wafers are subjected to a drying step after their deposition. This drying can be, but is not necessarily, carried out in a through-flow oven. During drying of the gels, these are compacted as a consequence of the expulsion of solvents, and also thermal degradation of formulation assistants and of oxide precursors, to give homogeneous and impermeable glass-like layers.

The printable and dried hybrid gels prepared in this way are particularly suitable for use as doping medium in the processing of silicon wafers for photovoltaic, microelectronic, micromechanical and micro-optical applications.

Correspondingly prepared hybrid gels are particularly suitable for the production of PERC, PERL, PERT and IBC solar cells (BJBC or BCBJ) and others, where the solar cells have further architectural features, such as MWT, EWT, selective emitter, selective front surface field, selective back surface field and bifaciality. Furthermore, the oxide media according to the invention can be used for the production of thin, impermeable glass layers which, as a consequence of thermal treatment, act as sodium and potassium diffusion barrier in LCD technology, in particular for the production of thin, impermeable glass layers on the top glass of a display, consisting of doped SiO₂, which prevent the diffusion of ions from the top glass into the liquid-crystalline phase.

With the aid of the printable hybrid gels prepared in accordance with the invention, it is possible to produce a touch-dry and abrasion-resistant layer on silicon wafers. This can be carried out in a process in which the hybrid gel which is printed onto the surface and which has been prepared by a process in accordance with the invention is dried in a temperature range between 50° C. and 750° C., preferably between 50° C. and 500° C., particularly preferably between 50° C. and 400° C., using one or more heating steps to be carried out sequentially (heating by means of a step function) and/or a heating ramp and compacted for vitrification, resulting in the formation of a touch-dry and abrasion-resistant layer, which can have thicknesses of up to 500 nm.

The layers vitrified on the surfaces are subsequently subjected to heat treatment at a temperature in the range between 750° C. and 1100° C., preferably between 850° C. and 1100° C., particularly preferably between 850° C. and 1000° C. Consequently, atoms which have a doping action on silicon, such as boron in the present case, are released to the substrate surface by silico-thermal reduction of their oxides thereon, causing a specific advantageous effect on the conductivity of the silicon substrate. It is particularly advantageous here that, owing to the heat treatment of the printed substrate, the dopants can be transported to depths of up to 1 μm, depending on the treatment duration and the treatment temperature, and electrical sheet resistances of less than 10 Ω/sqr can be established. The surface concentration of the dopant here can adopt values greater than or equal to 1*10¹⁹ to several 1*10²⁰ atoms/cm³ and is dependent on the type of dopant used in the printable hybrid gel. It has proven particularly advantageous here that subsequently the surface concentration of the parasitic doping of unintentionally protected (masked) surface regions of the silicon substrate which are not covered with the printable hybrid gels consequently differs by at least two powers of ten from the regions which have been specifically printed with the printable hybrid gels. In addition, this result can be achieved by printing the hybrid gel as doping medium onto silicon wafer surfaces which are hydrophilic (provided with wet-chemical and/or native oxide) and/or hydrophobic (provided with silane termination). The thin oxide layers formed from the hybrid gels applied to the substrate surfaces thus make it possible, by the choice of the following setting parameters:
composition of the hybrid gel (proportions of the oxide precursor having a doping action to those of the accompanying oxide precursors principally, but not exclusively, forming the glass)
the pretreatment of the glass, such as, for example, as a consequence of the irradiation with high-intensity light, for example laser radiation
treatment duration
treatment temperature,
   to decide directly on the diffusivity of the dopant, in this case of boron, the segregation coefficient thereof in the thin oxide layer and consequently on its effective dose of doping of the silicon wafer surfaces and thus specifically to influence the doping conditions. A corresponding situation applies to its diffusion-inhibiting and/or excluding and suppressing properties against undesired parasitic diffusion in the regions printed with the hybrid gel, induced by the simultaneous use of conventional doping sources which cause opposite doping, generally one comprising phosphorus, in regions not printed with the locally applied and dried hybrid gels according to the invention (so-called co-diffusion).

In generalised terms, this process for the production of touch-dry and abrasion-resistant oxidic layers which have a doping action on silicon and silicon wafers can be characterised in that

a) silicon wafers are printed with the hybrid gels according to the invention, the printed-on doping medium is dried, compacted and subsequently subjected to subsequent gas-phase diffusion with boron trichloride or boron tribromide, giving high doping in the printed regions and achieving lower doping in the regions which are subjected exclusively to the gas-phase diffusion,

or

b) as described above under a), and also applicable to the following points, the boron skin generally obtained on the wafer surface is

I. consumed with the aid of oxidative treatment at the end of the diffusion process, or

II. consumed with the aid of oxidative treatment during the diffusion process, or

III. removed from the wafer surface with the aid of subsequent sequential wet-chemical treatment with nitric and hydrofluoric acid,

or

c) silicon wafers are printed with the hybrid gels according to the invention in a structured manner, dried, compacted and subsequently treated in the same manner with a medium having the opposite doping action using the negative print layout used before, subjected to subsequent gas-phase diffusion with, for example, phosphoryl chloride in the case of an n-type doping medium used or with, for example, boron trichloride or boron tribromide in the case of a p-type doping medium used, enabling high dopings to be obtained in the unprinted regions and lower dopings to be obtained in the printed regions, so long as the source concentration of the hybrid gels used has been set sufficiently low in a controlled manner as a consequence of the synthesis, and the glass obtained from the hybrid gel according to the invention and the doping medium having the opposite action each represent a diffusion barrier against the gas-phase diffusants transported from the gas phase to the wafer surface and deposited thereon,

or

d) silicon wafers are printed with the hybrid gels according to the invention in a structured manner, dried, compacted and subsequently treated in the same manner with a medium having the opposite doping action using the negative print layout used before, subjected to subsequent gas-phase diffusion with, for example, phosphoryl chloride in the case of an n-type doping medium used or with, for example, boron trichloride or boron tribromide in the case of a p-type doping medium used, enabling low dopings to be obtained in the unprinted regions and high dopings to be obtained in the printed regions, so long as the source concentration of the hybrid gels used has been set to a sufficiently high concentration in a controlled manner as a consequence of the synthesis, and the glass obtained from the hybrid gel according to the invention and the doping medium having the opposite action each represent a diffusion barrier against the gas-phase diffusants transported from the gas phase to the wafer surface and deposited thereon,

or

e) hybrid gel deposited over the entire surface of the silicon wafer is dried and/or compacted, and local doping of the underlying substrate material is initiated from the compacted hybrid gel having a doping action with the aid of laser irradiation,

or

f) hybrid gel according to the invention deposited over the entire surface of the silicon wafer is dried and compacted, and doping of the underlying substrate is initiated from the compacted hybrid gel having a doping action with the aid of suitable heat treatment, and local doping of the underlying substrate material is subsequently augmented with subsequent local laser irradiation, and the dopant is driven deeper into the volume of the substrate,

or

g) the silicon wafer is printed with the hybrid gels according to the invention, either over the entire surface or locally, optionally with alternating structures, the printed structures are dried and compacted, the negatives of the alternating structures are printed with the aid of materials having the opposite doping action and brought to structured doping of the substrate as a consequence of suitable heat treatment,

or

h) the silicon wafer is printed with the hybrid gels according to the invention, either over the entire surface or locally, optionally in an alternating structure sequence of any desired structure width, for example line width, adjacent to unprinted silicon surface likewise characterised by any desired structure width, the printed structures are dried and compacted, after which the wafer is subsequently subjected to conventional gas-phase diffusion and doping by means of phosphoryl chloride or phosphorus pentoxide and the hybrid gel applied either locally or over the entire surface at the same time functions as diffusion barrier against the dopant provided via the gas phase and consequently the wafer surfaces not printed with the hybrid gel according to the invention are subjected to the opposite doping, in this case with phosphorus; if necessary, the opposite surface printed with the hybrid gel must or can be etched back in a suitable manner by means of suitable wet-chemical etching steps,

or

i) the silicon wafer is printed with the hybrid gels according to the invention, either over the entire surface or locally, optionally in an alternating structure sequence of any desired structure width, for example line width, adjacent to unprinted silicon surface likewise characterised by any desired structure width, the printed structures are dried and compacted, after which the wafer surface can subsequently be provided over the entire surface with a doping medium inducing the opposite majority charge carrier polarity onto the already printed wafer surface and also still open, i.e. unprinted wafer surface (encapsulation), where the last-mentioned doping media can be printable sol-gel-based oxidic doping materials, other printable doping inks and/or pastes, APCVD and/or PECVD glasses provided with dopants, and also dopants from conventional gas-phase diffusion and doping, and the doping media arranged in an overlapping manner and having a doping action are brought to doping of the substrate as a consequence of suitable heat treatment and in this context the lowest printed hybrid gel having a doping action must, as a consequence of suitable segregation coefficients and inadequate diffusion lengths, act as diffusion barrier against the doping medium located on top which induces the contrary majority charge carrier polarity; where furthermore the other side of the wafer surface may, but does not necessarily have to be, covered by means of another diffusion barrier deposited in another manner (printed, CVD, PVD), such as, for example, silicon dioxide or silicon nitride or silicon oxynitride,

or

j) the silicon wafer is printed with the hybrid gels according to the invention, either over the entire surface or locally, optionally in an alternating structure sequence of any desired structure width, for example line width, adjacent to unprinted silicon surface likewise characterised by any desired structure width, the printed structures are dried and compacted, after which the wafer surface can subsequently be provided over the entire surface with a doping medium inducing the opposite majority charge carrier polarity onto the already printed wafer surface and also still open, i.e. unprinted wafer surface (encapsulation), after which the wafer surface can subsequently be provided over the entire surface with a doping medium inducing the opposite majority charge carrier polarity onto the already printed wafer surface, where the last-mentioned doping media can be printable sol-gel-based oxidic doping materials, other printable doping inks and/or pastes, APCVD and/or PECVD glasses provided with dopants, and also dopants from conventional gas-phase diffusion and doping, and the doping media arranged in an overlapping manner and having a doping action are brought to doping of the substrate as a consequence of suitable heat treatment and in this context the lowest printed hybrid gel having a doping action must, as a consequence of suitable segregation coefficients and inadequate diffusion lengths, act as diffusion barrier against the doping medium located on top which induces the contrary majority charge carrier polarity; where furthermore the other side of the wafer surface may, but does not necessarily have to be, covered by means of another dopant source deposited in another manner (printable sol-gel-based oxidic doping materials, other printable doping inks and/or pastes, APCVD and/or PECVD glasses provided with dopants, and also dopants from conventional gas-phase diffusion) which is able to induce the same or also opposite doping as that from the lowest layer of the opposite wafer surface.

In the process characterised in this way, simultaneous co-diffusion takes place in a simple manner by temperature treatment of the layers formed from the printed-on hybrid gels, with formation of n- and p-type layers or such layers exclusively of a single majority charge carrier polarity, which may have different doses of dopant.

For the formation of hydrophobic silicon wafer surfaces, the glass layers formed in this process after the printing of the hybrid gels according to the invention, drying and compaction thereof and/or doping by temperature treatment are etched with an acid mixture comprising hydrofluoric acid and optionally phosphoric acid, where the etch mixture used may comprise, as etchant, hydrofluoric acid in a concentration of 0.001 to 10% by weight or 0.001 to 10% by weight of hydrofluoric acid and 0.001 to 10% by weight of phosphoric acid in a mixture. The dried and compacted doping glasses can furthermore be removed from the wafer surface using the following etch mixtures: buffered hydrofluoric acid mixtures (BHF), buffered oxide etch mixtures, etch mixtures consisting of hydrofluoric and nitric acid, such as, for example, the so-called p-etches, R-etches, S-etches or etch mixtures, etch mixtures consisting of hydrofluoric and sulfuric acid, where the above-mentioned list makes no claim to completeness.

The novel high-viscosity doping pastes can be synthesised on the basis of the sol-gel process and can be formulated further if this is necessary.

One synthetic method is based on the dissolution of oxide precursors of aluminium oxide in a solvent or solvent mixture, preferably selected from the group high-boiling glycol ethers or preferably high-boiling glycol ethers and alcohols, to which a suitable acid, preferably a carboxylic acid, and here particularly preferably formic acid or acetic acid, is subsequently added, and which is completed by the addition of suitable complexing agents and chelating agents, such as, for example, suitable β-diketones, such as acetyl-acetone or, for example, 1,3-cyclohexanedione, α- and β-ketocarboxylic acids and esters thereof, such as, for example, pyruvic acid and esters thereof, acetoacetic acid and ethyl acetoacetate, dihydroxybenzoic acids, such as, for example, 3,5-dihydroxybenzoic acid, and/or oximes, such as, for example, acetaldoxime, and further cited compounds of this type, and also any desired mixtures of the above-mentioned complexing agents, chelating agents and agents which control the degree of condensation. A mixture consisting of the above-mentioned solvent or solvent mixture and water is then added dropwise to the solution of the aluminium oxide precursor at room temperature, and the mixture is subsequently warmed under reflux at 80° C. for up to 24 h. Gelling of the aluminium oxide precursor can be controlled specifically via the molar ratio of the aluminium oxide precursor to water, to the acid used and also the molar amounts and type of the complexing agents employed. The synthesis durations necessary in each case are likewise dependent on the above-mentioned molar ratios. The readily volatile and desired parasitic by-products occurring in the reaction are subsequently removed from the finished reaction mixture, which is optionally already furthermore diluted, by means of vacuum distillation. The vacuum distillation is achieved by stepwise reduction of the final pressure to 30 mbar at a constant temperature of 70° C. The hybrid gels are adjusted with respect to their desired properties, either after or even before the distillative treatment, by specific addition of suitable solvents which favour the rheology and printability of the paste, such as, for example, high-boiling glycols, glycol ethers, glycol ether carboxylates and furthermore solvents such as terpineol, Texanol, butyl benzoate, benzyl benzoate, dibenzyl ether, butyl benzyl phthalate, and solvent mixtures, and optionally diluted. In parallel to the dilution and adjustment of the paste properties, a mixture consisting of condensed oxide precursors of silicon dioxide and boron oxide is added. For this purpose, precursors of boron oxide are initially introduced in a solvent, such as, for example, dibenzyl ether, butyl benzyl phthalate, benzyl benzoate, butyl benzoate, THF or a comparable solvent, a suitable carboxylic anhydride, such as, for example, acetic anhydride, formyl acetate or propionic anhydride or a comparable anhydride, is added, and dissolved or brought to reaction under reflux until a clear solution is present. Suitable precursors of silicon dioxide, optionally pre-dissolved in the reaction solvent used, are added dropwise to this solution. The reaction mixture is subsequently warmed or refluxed for up to 24 h. After the mixing of all components, the paste rheology can furthermore be adjusted and rounded off in accordance with specific requirements corresponding to the assistants and additives likewise already described in detail above, where the use according to the invention of waxes and wax-like compounds has a particular role. The waxes and wax-like compounds are dissolved or melted in the gelled paste mixture, if necessary with refluxing and with intimate stirring. The entire formulation is subsequently allowed to cool with intimate stirring, during which the desired properties of the finished pseudoplastic mixture become established. Depending on the type of the waxes and wax-like compounds used in accordance with the invention, homogeneous one-phase or emulsified two-phase mixtures are obtained.

An alternative synthetic method is based on the preparation of a condensed sol of oxide precursors of silicon dioxide and boron oxide. For this purpose, precursors of boron oxide are initially introduced in a solvent, such as, for example, dibenzyl ether, butyl benzyl phthalate, benzyl benzoate, butyl benzoate, THF or a comparable solvent, a suitable carboxylic anhydride, such as, for example, acetic anhydride, formyl acetate or propionic anhydride or a comparable anhydride, is added and dissolved or brought to reaction under reflux until a clear solution is present. Suitable precursors of silicon dioxide, optionally pre-dissolved in the reaction solvent used, are added dropwise to this solution. The reaction mixture is subsequently warmed or refluxed for up to 24 h. Suitable solvents, such as, for example, glycols, glycol ethers, glycol ether carboxylates and furthermore solvents such as terpineol, Texanol, butyl benzoate, benzyl benzoate, dibenzyl ether, butyl benzyl phthalate, or solvent mixtures thereof, in which suitable complexing agents and chelating agents, such as, for example, suitable β-diketones, such as acetylacetone or, for example, 1,3-cyclohexanedione, α- and β-ketocarboxylic acids and esters thereof, such as, for example, pyruvic acid and esters thereof, acetoacetic acid and ethyl acetoacetate, dihydroxybenzoic acids, such as, for example, 3,5-dihydroxybenzoic acid, and/or oximes, such as, for example, acetaldoxime, and further cited compounds of this type, and also any desired mixtures of the above-mentioned complexing agents, chelating agents and agents which control the degree of condensation, which are already pre-dissolved in the presence of water, are subsequently added to the sol, and the mixture is stirred, where the temperature of the reaction mixture may increase at the same time. The duration of mixing of the two solutions can be between 0.5 minute and five hours. The entire mixture is heated with the aid of an oil bath, whose temperature is generally set to 155° C. After a duration of mixing of the entire solution completed from the two part-solutions which is known as suitable, a suitable aluminium oxide precursor, which has itself been pre-dissolved in one of the above-mentioned solvents or solvent mixtures, is subsequently added dropwise or allowed to run into the reaction mixture in such a way that the addition is completed in a time window of five minutes since the beginning of the addition. The reaction mixture now completed in this way is then warmed under reflux for one to four hours. The warm gelled mixture can then be modified with respect to its rheological properties in accordance with desired requirements using further assistants already mentioned above, but in particular and particularly preferably through the use of the waxes and wax-like compounds to be used in accordance with the invention. Depending on the type of the waxes and wax-like compounds used in accordance with the invention, homogeneous one-phase or emulsified two-phase mixtures are obtained.

In the following examples, the preferred embodiments of the present invention are reproduced.

As stated above, the present description enables the person skilled in the art to use the invention comprehensively. Even without further comments, it will therefore be assumed that a person skilled in the art will be able to utilise the above description in the broadest scope.

Should anything be unclear, it goes without saying that the cited publications and patent literature should be consulted. Accordingly, these documents are regarded as part of the disclosure content of the present description.

For better understanding and in order to illustrate the invention, examples are given below which are within the scope of protection of the present invention. These examples also serve to illustrate possible variants. Owing to the general validity of the inventive principle described, however, the examples are not suitable for reducing the scope of protection of the present invention to these alone.

Furthermore, it goes without saying to the person skilled in the art that, both in the examples given and also in the remainder of the description, the component amounts present in the compositions always only add up to 100% by weight, mol-% or vol.-%, based on the entire composition, and cannot exceed this, even if higher values could arise from the per cent ranges indicated. Unless indicated otherwise, % data are therefore regarded as % by weight, mol-% or vol.-%.

The temperatures given in the examples and description and in the claims are always in ° C.

### EXAMPLES

### Example 1

55.2 g of ethylene glycol monobutyl ether (EGB) and 20.1 g of aluminium tri-sec-butylate (ASB) are initially introduced in a glass flask and stirred until a homogeneous mixture forms. 7.51 g of glacial acetic acid, 0.8 g of acetaldoxime and 0.49 g of acetylacetone are added to this mixture with stirring.

1.45 g of water, dissolved in 5 g of EGB, are subsequently added dropwise, and the mixture is refluxed at 80° C. for five hours. After warming, the mixture is subjected to a vacuum distillation at 70° C. until a final pressure of 30 mbar has been reached. The mass loss of readily volatile reaction products is 12.18 g. The distilled mixture is subsequently diluted with 62.3 g of Texanol and a further 65 g of EGB, and a mixed condensed sol consisting of precursors of boron oxide and silicon dioxide is added. The hybrid sol comprising silicon dioxide and boron oxide is to this end prepared as follows: 6.3 g of tetraacetoxy diborate are initially introduced in 40 g of benzyl benzoate, and 15 g of acetic anhydride are added. The mixture is warmed to 80° C. in an oil bath, and, when a clear solution has formed, 4.6 g of dimethyldimethoxysilane are added, and the entire mixture is left to react for 45 minutes with stirring. The hybrid sol is subsequently likewise subjected to a vacuum distillation at 70° C. until a final pressure of 30 mbar has been reached, where the mass loss of readily volatile reaction products is 7.89 g. 9 g of Synchro wax are added to the entire 110 g of mixture, and the mixture is warmed at 150° C. with stirring until everything has dissolved and the mixture is clear. The mixture is subsequently allowed to cool with vigorous stirring. A pseudoplastic and very readily printable paste forms.

### Example 2

40 g of benzyl benzoate and 6.3 g of tetraacetoxy diborate and 15 g of acetic anhydride are initially introduced in a glass flask and warmed to 80° C. in an oil bath with stirring. When a clear solution has been achieved, silicon dioxide precursors, in this case a mixture consisting of 2.3 g of dimethyldimethoxysilane and 3.4 g of bis[triethoxysilyl]ethane, are added dropwise to the solution. The mixture is left to react at 80° C. for 30 minutes with stirring. 75 g of Texanol, 150 g of EGB, 1 g of water, 1 g of 3,5-dihydroxybenzoic acid and 1.75 g of 1,3-cyclohexanedione are subsequently added to this mixture. The mixture is stirred for 20 minutes, during which the temperature of the oil bath is raised to 155° C. After mixing of the solution, 21 g of ASB, dissolved in 60 g of benzyl benzoate, are added dropwise to this solution. The completed mixture is left to react for a further hour with vigorous stirring. After the reaction, the mixture is subjected to a vacuum distillation at 70° C. until a final pressure of 30 mbar has been reached, where the mass loss is 20.3 g. 8.2 g of beeswax are added to 120 g of the mixture, and the mixture is warmed at 150° C. with stirring until a clear solution forms. This solution is slowly cooled with stirring. In a parallel batch, 9.5 g of Synchro wax are likewise added to 120 g of the mixture, and the mixture is likewise warmed at 150° C. until a clear solution forms, which is cooled with vigorous stirring. Pseudoplastic and very readily printable pastes are obtained.

### Example 3

The paste according to Example 1 is printed onto a wafer with the aid of a conventional screen-printing machine and a 350 mesh screen with a wire thickness of 16 μm (stainless steel) and an emulsion thickness of 8-12 μm using a doctor-blade speed of 170 mm/s and a doctor-blade pressure of 1 bar and subsequently subjected to drying in a through-flow oven. The heating zones in the through-flow oven are for this purpose set to 350/350/375/375/375/400/400° C.

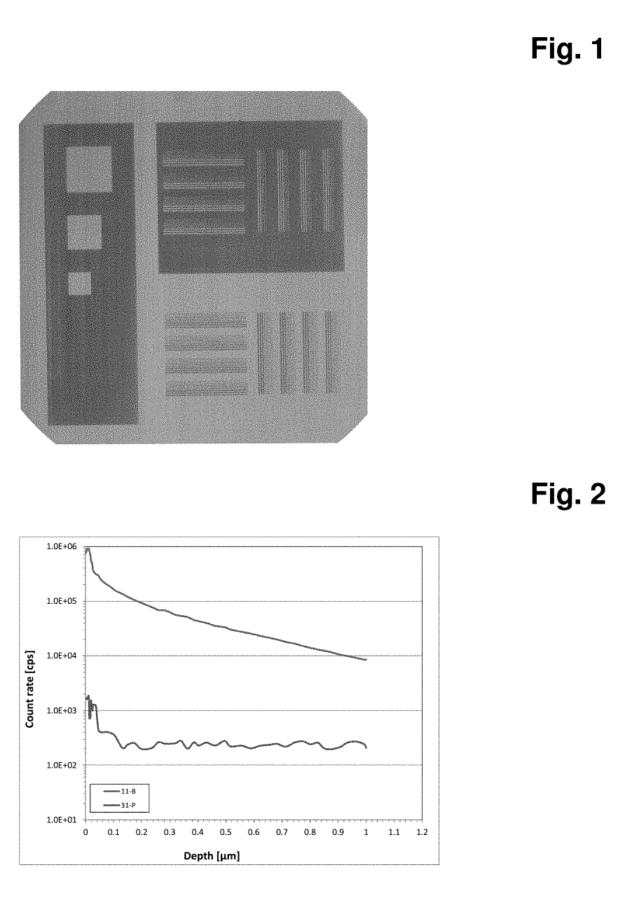

FIG. 1 shows a silicon wafer printed with the hybrid gel according to the invention after drying in a through-flow oven. The hybrid gel used corresponds to a composition which has been prepared in accordance with Example [lacuna].

### Example 4

The paste according to Example 1 is printed over a large area onto a rough CZ wafer surface (n-type) with the aid of a conventional screen-printing machine and a 280 mesh screen with a wire thickness of 25 μm (stainless steel). The wet application rate is 1.5 mg/cm². The printed wafer is subsequently dried at 300° C. on a conventional laboratory hotplate for 3 minutes and subsequently subjected to a diffusion process. To this end, the wafer is introduced into a diffusion oven at approximately 700° C., and the oven is subsequently heated to a diffusion temperature of 950° C. The wafer is kept at this plateau temperature for 30 minutes and kept in a nitrogen atmosphere comprising 0.2% v/v of oxygen. After the boron diffusion, the wafer is subjected to phosphorus diffusion with phosphoryl chloride at low temperature, 880° C., in the same process tube. After the diffusions and cooling of the wafer, the latter is freed from glasses present on the wafer surfaces by means of etching with dilute hydrofluoric acid. The region which had previously been printed with the boron paste according to the invention has a hydrophilic wetting behaviour on rinsing of the wafer surface with water, which is a clear indication of the presence of a boron skin in this region. The sheet resistance determined in the surface region printed with the boron paste is 195 Ω/sqr (p-type doping). The regions not protected by the boron paste have a sheet resistance of 90 Ω/sqr (n-type doping). The SIMS (secondary ion mass spectrometry) depth profile of the dopants is determined in the region of the surface which was printed by means of the boron paste according to the invention. In the region covered with the B paste, boron doping extending from the wafer surface into that of the silicon is determined, apart from the n-type base doping. The printed-on paste layer thus acts as diffusion barrier against typical phosphorus diffusion.

FIG. 2 shows the SIMS profile of a rough silicon surface which has been printed with the boron paste according to the invention and subsequently subjected to gas-phase diffusion with phosphoryl chloride. Owing to the rough surface, only relative concentrations in the form of count rates can be obtained.

### Example 5

481.3 g of ethylene glycol monobutyl ether (EGB) and 82 g of aluminium trisec-butylate (ASB) are initially introduced in a glass flask and stirred until a homogeneous mixture forms. 31 g of glacial acetic acid, 3.2 g of acetaldoxime and 2.2 g of 1,3-cyclohexanedione are added to this mixture in the said sequence with stirring. 12.1 g of water, dissolved in 20 g of EGB, are subsequently added dropwise, and the mixture is refluxed at 120° C. for 180 minutes (mixture 1). 25.4 g of tetraacetoxy diborate and 192 g of benzyl benzoate are initially introduced in a further glass flask. 61.4 g of acetic anhydride and 18.5 g of dimethoxydimethylsilane are stirred into the initially introduced mixture, and, when mixing is complete, the mixture is left to reflux in an oil bath held at a temperature of 130° C. (mixture 2). After cooling of the mixture, mixture 1 and mixture 2 are combined in a glass flask of suitable size with addition of 261 g of Texanol and 40 g of ethylene glycol monobutyl ether. The entire mixture is subsequently evaporated at 70° C. in a rotary evaporator until a final pressure of 30 mbar has been reached. The reaction yield is 1,160 g. The gel-form hybrid sol is subsequently transferred into a stirred container of suitable size, and 116 g of Synchro wax ERLC are added. The wax is melted with warming and vigorous stirring of the mixture at 150° C. and dissolved in the gel at elevated temperature. When the wax has dissolved completely, the supply of heat is interrupted, and the mixture is allowed to cool with stirring. After cooling, a buttery, pseudoplastic, yellowish-white, very readily printable paste is obtained.

The viscosity of the paste is 7.5 Pa*s at a shear rate of 25 1/s and a temperature of 23° C.

The paste is printed with the aid of a screen printer using a trampoline screen with stainless-steel fabric (400 mesh, 18 μm wire diameter, calendered, 8-12 μm emulsion on top of the fabric) onto wafers which have been subjected to alkaline polish-polishing, using the following printing parameters:

a screen separation of 2 mm, a printing speed of 200 mm/s, a flooding speed of likewise 200 mm/s, a doctor-blade pressure of 60 N during the printing operation and a doctor-blade pressure of 20 N during the flooding, and using a carbon fibre doctor blade with polyurethane rubber of Shore hardness of 65°.

The printed wafers are subsequently dried in a through-flow oven warmed to 400° C. The belt speed is 90 cm/s. The length of the heating zones is 3 m. The paste transfer rate is 0.65 mg/cm².

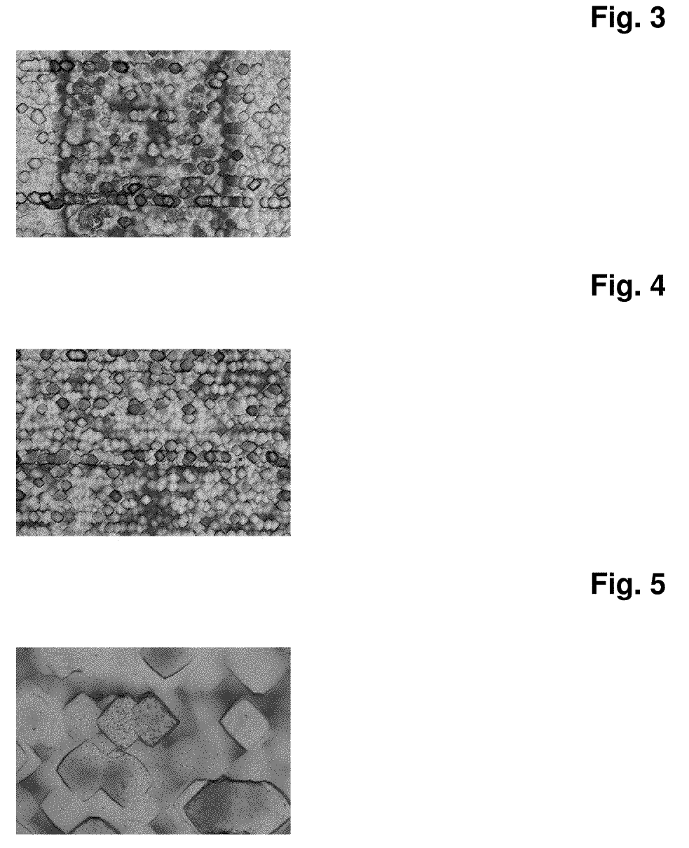

FIG. 3 shows the photomicrograph of a line screen-printed with a doping paste according to Example 5 and dried.

FIG. 4 shows a photomicrograph of a paste area screen-printed with a doping paste according to Example 5 and dried.

FIG. 5 shows a photomicrograph of a paste area screen-printed with a doping paste according to Example 5 and dried.

In a further procedure, both CZ n-type silicon wafers which have been subjected to alkaline polish-etching and also those which have been alkaline-textured and subsequently polished by means of acidic etches on one side are printed with the doping paste approximately over the entire surface (˜93%).

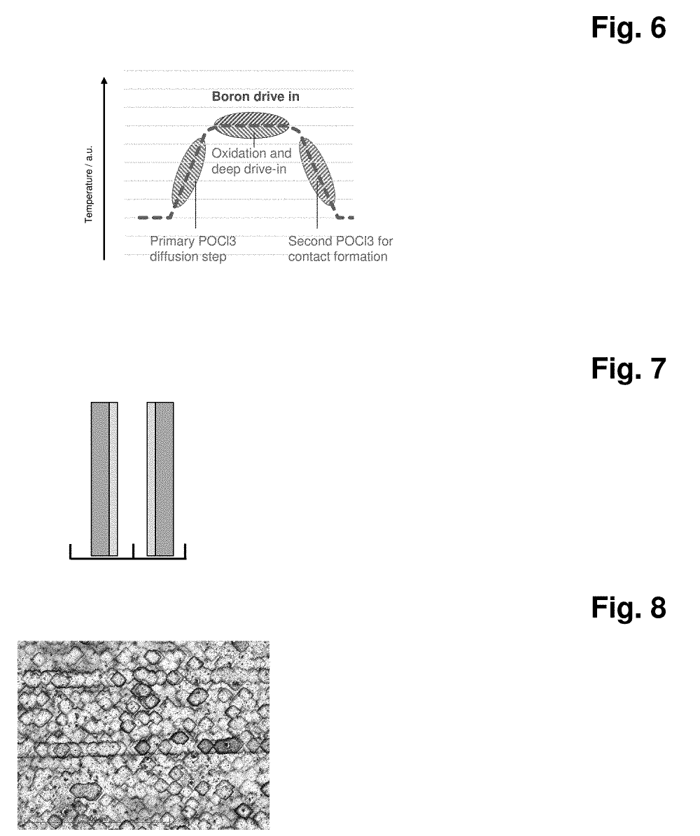

The printing is carried out using a screen with stainless-steel fabric (400/18, 10 μm emulsion thickness over the fabric). The paste application rate is 0.9 mg/cm². The wafers are dried at 400° C. on a hotplate for three minutes and subsequently subjected to co-diffusion at a plateau temperature of 950° C. for 30 minutes. During the co-diffusion, the wafer is diffused and doped with boron on the side printed with the boron paste, whereas the wafer side or surface that is not printed with boron paste is diffused and doped with phosphorus. The phosphorus diffusion is in this case achieved with the aid of phosphoryl chloride vapour, which is introduced into the hot oven atmosphere transported by a stream of inert gas. As a consequence of the high temperature prevailing in the oven and the oxygen simultaneously present in the oven atmosphere, the phosphoryl chloride is combusted to give phosphorus pentoxide. The phosphorus pentoxide precipitates in combination with a silicon dioxide forming on the wafer surface owing to the oxygen present in the oven atmosphere. The mixture of the silicon dioxide with the phosphorus pentoxide is also referred to as PSG glass. The doping of the silicon wafer takes place from the PSG glass on the surface. On surface regions on which boron paste is already present, a PSG glass can only form on the surface of the boron paste. If the boron paste acts as diffusion barrier against phosphorus, phosphorus diffusion cannot take place at points at which boron paste is already present, but instead only diffusion of boron itself which diffuses out of the paste layer into the silicon wafer. This type of co-diffusion can be carried out in various embodiments. In principle, the phosphoryl chloride can be combusted in the oven at the beginning of the diffusion process. The beginning of the process in the industrial production of solar cells is generally taken to mean a temperature range between 600° C. and 800° C., in which the wafers to be diffused can be introduced into the diffusion oven. Furthermore, combustion can take place in the oven cavity during heating of the oven to the desired process temperature. Phosphoryl chloride can accordingly also be introduced into the oven during holding of the plateau temperature, and also during cooling of the oven or perhaps also after a second plateau temperature, which may be higher and/or also lower than the first plateau temperature, has been reached. Of the above-mentioned possibilities, any desired combinations of the phases of possible introduction of phosphoryl chloride into the diffusion oven can also be carried out, depending on the respective requirements. Some of these possibilities have been sketched. In FIG. 6, the possibility of use of a second plateau temperature is not depicted.

The wafers printed with the boron paste are subjected, as described, to a co-diffusion process in which the phosphoryl chloride is introduced into the diffusion oven before the plateau temperature which is necessary in order to achieve boron diffusion, in this case 950° C., has been reached. During the diffusion, the wafers are arranged in pairs in the process boat in such a way that their sides printed with boron paste in each case face one another. In each case, a wafer is accommodated in a slot of the process boat. The nominal separation between the substrates is thus about 2.5 mm. After the diffusion, the wafers are subjected to a glass etch in dilute hydrofluoric acid and their sheet resistances are subsequently measured by means of four-point measurement. The side of the wafer diffused with the boron paste has a sheet resistance of 41 Ω/□, while the opposite side of the wafer printed with the boron paste has a sheet resistance of 68 Ω/□. With the aid of a p/n tester, it is demonstrated that the side that has a sheet resistance of 41 Ω/□ is exclusively p-doped, i.e. doped with boron, whereas the opposite side, which has a sheet resistance of 68 Ω/□, is exclusively n-doped, i.e. doped with phosphorus. There is no fundamental difference between the sheet resistances on the wafers subjected to alkaline polish-etching and those in which the alkaline texture has been subjected to subsequent acidic polishing on one side—both on the wafer side doped with phosphorus and also on the wafer side doped with boron.

FIG. 6 shows a photomicrograph of a line screen-printed with a doping paste according to Example 5 and dried.

FIG. 7 shows an arrangement of wafers in a process boat during a co-diffusion process. The wafer surfaces printed with boron paste are opposite.

### Example 6

6.16 g of dimethoxydimethylsilane, 30.13 g of aluminium diisopropylate acetoacetic ester chelate and 8.41 g of tetraacetoxy diborate are dissolved and suspended in 50.2 g of 1,4-dioxane in a glass flask. The reaction mixture is warmed to 80° C. in an oil bath and refluxed for a period of 8 hours and 60 hours. During the reaction, the transparent mixture changes from colourless to a yellow-orange colour. After completion of the reaction, the reaction mixture is treated in a rotary evaporator and evaporated to dryness. The distillation loss is 60.02 g. 10 g of the residue are dissolved in 35.9 g of diethylene glycol ether dibenzoate and subsequently diluted with 34.7 g of butoxyethoxyethyl acetate and 5 g of triethyl orthoformate. The solution is subsequently warmed to 90° C., and 8.5 g of ERLC wax (a triglyceride having chain lengths of the fatty acids present of C18 to C36) are added and dissolved in the mixture. The solution is allowed to cool with vigorous stirring. During the cooling, some of the wax precipitates out of the solution and is emulsified in the mixture. A pseudoplastic, viscoelastic paste (dynamic viscosity of 11.2 Pa*s at a shear rate of 25 1/s and a temperature of 23° C.) is formed which can be printed very well onto polish-etched silicon wafer surfaces under the printing parameters mentioned in the examples outlined above. The paste is printed with the aid of a screen printer using a trampoline screen with stainless-steel fabric (400 mesh, 18 μm wire diameter, calendered, 8-12 ρm emulsion on top of the fabric) onto wafers which have been subjected to alkaline polish-etching, using the following printing parameters:

a screen separation of 2 mm,

a printing speed of 200 mm/s,

a flooding speed of likewise 200 mm/s,

a doctor-blade pressure of 60 N during the printing operation and a doctor-blade pressure of 20 N during the flooding, and using a carbon fibre doctor blade with polyurethane rubber having a Shore hardness of 65°.

The printed wafers are subsequently dried in a through-flow oven warmed to 400° C. The belt speed is 90 cm/s. The length of the heating zones is 3 m. The paste transfer rate is 1.15 mg/cm².

FIG. 8 shows the photomicrograph of a line screen-printed with a doping paste according to Example 6 and dried.

1. Printable hybrid gels based on precursors of inorganic oxides which are printed selectively or over the entire surface onto silicon surfaces by means of a suitable printing process for the purposes of local and/or full-area diffusion and doping on one side for the production of solar cells, dried and subsequently brought to specific doping of the substrate itself by means of a suitable high-temperature process for release of the boron oxide precursor present in the printed-on layer to the underlying substrate.

2. Printable, paste-form hybrid gels according to claim 1, characterised in that they are compositions based on precursors of silicon dioxide, aluminium oxide and boron oxide.

3. Hybrid gels according to claim 1, characterised in that they are compositions based on precursors of silicon dioxide, aluminium oxide and boron oxide which are employed as a mixture.

4. Printable, paste-form hybrid gels according to claim 1, characterised in that they have been obtained on the basis of precursors of silicon dioxide, selected from the group of symmetrically and asymmetrically mono- to tetrasubstituted carboxy-, alkoxy- and alkoxyalkylsilanes, in particular alkylalkoxysilanes in which the central silicon atom can have a degree of substitution of 1 to 4 with at least one hydrogen atom bonded directly to the silicon atom, and where furthermore a degree of substitution relates to the number of possible carboxyl and/or alkoxy groups present which, both in the case of alkyl and/or alkoxy and/or carboxyl groups, contain individual or different saturated, unsaturated branched, unbranched aliphatic, alicyclic and aromatic radicals, which may in turn be functionalised at any desired position of the alkyl, alkoxide or carboxyl radical by heteroatoms selected from the group O, N, S, Cl and Br, and mixtures of these precursors.

5. Printable, paste-form hybrid gels according to claim 1, characterised in that they have been obtained on the basis of precursors of silicon dioxide, selected from the group tetraethyl orthosilicate, triethoxysilane, ethoxytrimethylsilane, dimethyldimethoxysilane, dimethyldiethoxysilane, triethoxyvinylsilane, bis[triethoxysilyl]ethane and bis[diethoxymethylsilyl]ethane, and mixtures thereof.

6. Printable, paste-form hybrid gels according to claim 1, characterised in that they have been obtained on the basis of precursors of aluminium oxide, selected from the group of symmetrically and asymmetrically substituted aluminium alcoholates (alkoxides), aluminium tris(β-diketones), aluminium tris(β-ketoesters), aluminium soaps, aluminium carboxylates, and mixtures thereof.

7. Printable, paste-form hybrid gels according to claim 1, characterised in that they have been obtained on the basis of precursors of aluminium oxide, selected from the group aluminium triethanolate, aluminium triisopropylate, aluminium tri-sec-butylate, aluminium tributylate, aluminium triamylate and aluminium triisopentanolate, aluminium acetylacetonate or aluminium tris(1,3-cyclohexanedionate), aluminium monoacetylacetonate monoalcoholate, aluminium tris(hydroxyquinolate), mono- and dibasic aluminium stearate and aluminium tristearate, aluminium acetate, aluminium triacetate, basic aluminium formate, aluminium triformate and aluminium trioctanoate, aluminium hydroxide, aluminium metahydroxide and aluminium trichloride, and mixtures thereof.

8. Printable, paste-form hybrid gels according to claim 1, characterised in that they have been obtained on the basis of precursors of boron oxide, selected from the group of alkyl borates, boric acid esters of functionalised 1,2-glycols, boric acid esters of alkanolamines, mixed anhydrides of boric acid and carboxylic acids, and mixtures thereof.

9. Printable, paste-form hybrid gels according to claim 1, characterised in that they have been obtained on the basis of precursors of boron oxide, selected from the group boron oxide, diboron oxide, triethyl borate, triisopropyl borate, boric acid glycol ester, boric acid ethylene glycol ester, boric acid glycerol ester, boric acid ester of 2,3-dihydroxysuccinic acid, tetraacetoxy diborate, and boric acid esters of the alkanolamines ethanolamine, diethanolamine, triethanolamine, propanolamine, dipropanolamine and tripropanolamine.

10. A method of preparing a printable, paste-form hybrid gels according to claim 1 comprising bringing a precursor to partial or complete intra- and/or interspecies condensation under water-containing or anhydrous conditions with the aid of the sol-gel technique, either simultaneously or sequentially, forming storage-stable, very readily printable and printing-stable formulations having a viscosity of >500 mPa*s.

11. A method according to claim 10, wherein a volatile reaction assistants and by-products are removed during the condensation reaction.

12. A method according to claim 10, further comprising adjusting the precursor concentrations, the water and catalyst content and the reaction temperature and time.

13. A method according to claim 10, wherein the condensation-controlling agents in the form of complexing agents and/or chelating agents, various solvents in defined amounts, based on the total volume, are added to control the degree of gelling of the hybrid sols and gels formed.

14. A method according to claim 10, further comprising adding waxes and/or wax-like compounds in an amount of up to 25%, based on the total amount of the composition, for the establishment of the pasty and pseudoplastic properties, where the waxes and wax-like compounds are selected from the group beeswax, Synchro wax, lanolin, carnauba wax, jojoba, Japan wax, fatty acids and fatty alcohols, fatty glycols, esters of fatty acids and fatty alcohols, fatty aldehydes, fatty ketones and fatty β-diketones and mixtures thereof, where the above-mentioned classes of substance should each contain branched and unbranched carbon chains having chain lengths greater than or equal to twelve carbon atoms, have a thickening action in one phase and/or two phases, emulsifying or suspending.

15. Use of the printable, paste-form hybrid gels according to claim 1 in a process for the production of solar cells, in which they are printed onto silicon surfaces for the purposes of local and/or full-area diffusion and doping on one side by means of screen printing processes in the production of solar cells, dried and subsequently brought to specific doping of the substrate itself by means of a suitable high-temperature process for release of the boron oxide precursor present in the gel to the substrate located beneath the hybrid gel.

16. Use of the printable, paste-form hybrid gels according to claim 1 in a process for the production of highly efficient solar cells doped in a structured manner.

17. Use of the printable, paste-form hybrid gels according to claim 1 for the processing of silicon wafers for photovoltaic, microelectronic, micromechanical and micro-optical applications.

18. Use of the printable, paste-form hybrid gels according to claim 1 for the production of PERC, PERL, PERT and IBC solar cells and others, where the solar cells have further architectural features, such as MWT, EWT, selective emitter, selective front surface field, selective back surface field and bifaciality.

19. Use of the printable, paste-form hybrid gels according to claim 1 for the production of a touch-dry and abrasion-resistant layer on silicon wafers, where the hybrid gel printed onto the surface is dried in a temperature range between 50° C. and 750° C., preferably between 50° C. and 500° C., particularly preferably between 50° C. and 400° C., using one or more heating steps to be carried out sequentially, optionally heating by means of a step function and/or a heating ramp, and compacted for vitrification, resulting in the formation of touch-dry and abrasion-resistant layers having a thickness of up to 500 nm.

20. Use according to claim 19 for influencing the conductivity of the substrate, where silicon-doping boron atoms are released from the layers vitrified on the surfaces by heat treatment at a temperature in the range between 750° C. and 1100° C., preferably between 850° C. and 1100° C., particularly preferably between 850° C. and 1000° C.

21. Use of the printable, paste-form hybrid gels according to claim 1 for doping a printed substrate by suitable temperature treatment, where doping of the unprinted silicon wafer surfaces with dopants of the opposite polarity is induced simultaneously and/or sequentially by means of conventional gas-phase diffusion and where the printed-on hybrid gel acts as diffusion barrier against the dopants of the opposite polarity.

22. Process for the doping of silicon wafers, characterised in that
a) silicon wafers are printed locally on one or both sides or over the entire surface on one side with the paste-form hybrid gels according to claim 1, the printed-on gel is dried, compacted and subsequently subjected to subsequent gas-phase diffusion with, for example, phosphoryl chloride, giving p-type dopings in the printed regions and n-type dopings in the regions subjected exclusively to gas-phase diffusion, or
b) paste-form hybrid gel according to claim 1 is printed over a large area onto the silicon wafer and/or compacted, and local doping of the underlying substrate material is induced from the dried and/or compacted paste with the aid of laser irradiation, followed by high-temperature diffusion and doping for the production of two-stage p-type doping levels in the silicon, or
c) the silicon wafer is printed locally on one side with the paste-form hybrid gel, where the structured deposition may optionally have alternating lines, the printed structures are dried and compacted and subsequently coated over the entire surface with the aid of PVD- and/or CVD-deposited doped glasses which are able to induce doping of the opposite polarity in the silicon and encapsulated, and the entire overlapping structure is brought to structured doping of the silicon wafer by suitable high-temperature treatment, where the printed-on hybrid gel acts as diffusion barrier against the glass located on top and the dopant present therein.
